(19) United States
(12) Patent Application Publication
(10) Pub. No.: US 2011/0097867 A1
(43) Pub. Date: Apr. 28, 2011

(54) METHOD OF CONTROLLING GATE THICKNESSES IN FORMING FUSI GATES

(75) Inventors: Shun Wu LIN, Taichung City (TW); Matt YEH, Hsinchu (TW)

(73) Assignee: TAIWAN SEMICONDUCTOR MANUFACTURING COMPANY, LTD., Hsinchu (TW)

(21) Appl. No.: 12/819,701

(22) Filed: Jun. 21, 2010

Related U.S. Application Data
(60) Provisional application No. 61/254,016, filed on Oct. 22, 2009.

(51) Int. Cl. H01L 21/8234; H01L 21/336

(52) U.S. Cl. 438/294; 438/301; 257/E21.409; 257/E21.616

(57) ABSTRACT

A method of fabricating a semiconductor device is provided. In one embodiment, a gate structure is formed on a substrate, the gate structure having a gate dielectric layer and a first polysilicon layer formed above the gate dielectric layer. A passivation layer is formed above the first polysilicon layer. A second polysilicon layer is formed above the passivation layer. The second polysilicon layer and the passivation layer are removed. A metal layer is formed above the first polysilicon layer. The first polysilicon layer is reacted with the metal layer to silicide the first polysilicon layer. Any un-reacted metal layer is thereafter removed.

### CROSS-REFERENCE TO RELATED APPLICATIONS

The present application claims priority of U.S. Provisional Patent Application Ser. No. 61/254,016, filed on Oct. 22, 2009, which is incorporated herein by reference in its entirety.

### TECHNICAL FIELD

The present disclosure relates generally to the fabrication of fully-silicided (FUSI) gate structures, and more particularly, to a method of controlling the gate thicknesses in forming FUSI gate structures.

### BACKGROUND

As the size of complementary metal oxide semiconductor (CMOS) devices continue to shrink down into the deep sub-micron region, it is desirable to use metal gates, such as FUSI gates to further reduce resistance and gate conductance, eliminate polysilicon depletion, and tune work function performance. A FUSI gate can be formed by depositing a metal layer (such as Ni, Ti, Co, Pt, etc.) over an exposed polysilicon gate layer, pre-annealing to provide the required diffusion, removing the unreacted metal, and then annealing the semiconductor structure to form a more stable silicide alloy gate electrode. The deposited metal reacts with the exposed polysilicon gate to transform the poly gate fully into a silicided gate.

While FUSI gate structures provide the above advantages, they introduce difficulties in the manufacturing control process that need to be overcome. One such difficulty with conventional FUSI fabrication methods is in controlling the thickness uniformity of the exposed polysilicon gate layer. Prior to depositing the metal layer over the exposed polysilicon layer, the polysilicon layer is typically etched back by either dry or wet etching to reduce its thickness. This etching process typically produces a poly layer having non-uniform thickness (i.e., dishing profile). This may result in incomplete silicidation or inappropriate silicidation type of the FUSI gate leading to poor device performance.

For this reason and other reasons that will become apparent upon reading the following detailed description, there is a need for a method to precisely control the thickness of the polysilicon gate layer that avoids the shortcomings associated with conventional methods of forming FUSI gates.

### BRIEF DESCRIPTION OF DRAWINGS

The features, aspects, and advantages of the disclosure will become more fully apparent from the following detailed description, appended claims, and accompanying drawings in which:

FIGS. 1-5 are cross-sectional views of one embodiment of a semiconductor device during various fabrication stages thereof.

### DETAILED DESCRIPTION

In the following description, numerous specific details are set forth to provide a thorough understanding of embodiments of the present invention. However, one having an ordinary skill in the art will recognize that embodiments of the invention can be practiced without these specific details. In some instances, well-known structures and processes have not been described in detail to avoid unnecessarily obscuring embodiments of the present invention.

Exemplary structures and methods are provided below for fabricating a CMOS device according to some embodiments of the present invention. Although the exemplary embodiments are described as a series of steps, it will be appreciated that this is for illustration and not for the purpose of limitation. For example, some steps may occur in a different order than illustrated yet remain within the scope of the invention. In addition, not all illustrated steps may be required to implement some embodiments of the present invention. Furthermore, the structures and methods according to some embodiments of the invention may be implemented in association with the fabrication or processing of other semiconductor structures not illustrated.

Generally, exemplary embodiments of the present invention provide silicided semiconductor structures and methods of forming these structures. FIGS. 1-5 illustrate an exemplary embodiment of the invention. Turning now to FIG. 1, there is shown a semiconductor device 10 having gate structures or transistors 40 formed on substrate 20. Semiconductor device 10 may comprise either NMOS structures, PMOS structures, or a combination thereof, for example as in a CMOS device. Substrate 20 may comprise a bulk semiconductor wafer, a silicon on insulator (SOI) wafer, silicon on sapphire (SOS) or other substrate compatible with integrated circuit manufacturing. Other materials, such as germanium, quartz, glass, and/or Si—Ge epi could alternatively be used for the substrate 20 or part of the substrate 20. Isolation structures 35, such as shallow trench isolation structures well-known in the art are also formed in substrate 20. Isolation structures 35 isolate or separate one transistor 40 from another transistor 40 and from other structures.

Transistor 40 comprises an oxide layer 50, a gate dielectric layer 60, and one or more polysilicon layers. As shown in FIG. 1, an oxide layer 50 is formed over the substrate 20. Oxide layer 50 may be formed by deposition processes and comprise insulating materials and may, in one embodiment have a thickness of from about 10 Angstroms to about 100 Angstroms. A gate dielectric layer 60 is thereafter formed over the oxide layer 50. Gate dielectric layer 60 comprises a non-conductive material (e.g., silicon oxide (i.e., SiO₂), silicon oxynitride, or a high dielectric constant (“high-K”) material such as hafnium-based metal-oxide). Depending on the material used for the dielectric layer 60, the dielectric layer 60 can be formed by a variety of techniques (e.g., thermal oxidation, thermal oxidation followed by a thermal nitridation, atomic layer deposition (ALD), or chemical vapor deposition (CVD)). In one embodiment, the gate dielectric layer 60 may have a thickness of from about 10 Angstroms to about 100 Angstroms, although other thicknesses are within the contemplated scope of the invention.

Whereas in the conventional method for forming FUSI gate structures where it would be difficult to control the thickness uniformity of the polysilicon layer prior to depositing a metal-containing layer for silicidation, an aspect of the present disclosure introduces an insertion layer or a passivation layer 100 in the gate structure 40 prior to the silicidation phase. As will be discussed further below, this passivation layer 100 is generally sandwiched in-between one or more polysilicon layers. During an etch-back procedure to remove the top poly layer to stop at the passivation layer and to remove the passivation layer thereafter, embodiments of the present invention provide a precise way of controlling the polysilicon thickness.

Referring back to FIG. 1, a first polysilicon layer 70 is then formed over the gate dielectric layer 60. The first polysilicon layer 70 may be formed, for example, by using a low-pressure chemical vapor deposition (LPCVD) process. In some embodiments, the first polysilicon layer 70 has a thickness of from about 50 Angstroms to about 800 Angstroms, although other thicknesses are within the contemplated scope of the invention. An insertion or passivation layer 100 is formed over the first polysilicon layer 70 and is used as an etch stop layer. The passivation layer 100 may comprise oxide, silicon oxide, nitride, silicon nitride, silicon oxynitride, or some other appropriate material. It is understood that the selection of the material for the passivation layer 100 is a matter of design choice, where the material should be compatible with the CMOS process flow and should have high etching selectivity relative to polysilicon. It is also understood that the thickness of the passivation layer 100 is also a matter of design choice, where the passivation layer 100 must be sufficiently thick so as to protect the underlying first polysilicon layer 70 from over-etching. In one embodiment, the passivation layer 100 has a thickness of from about 10 Angstroms to about 100 Angstroms, although other thicknesses are within the contemplated scope of the invention. The passivation layer 100 can be formed by a variety of techniques (e.g., thermal oxidation, thermal oxidation followed by a thermal nitridation, atomic layer deposition (ALD), or chemical vapor deposition (CVD)).

Although not shown in FIG. 1, a hard mask layer is formed atop the passivation layer 100. The hard mask layer may comprise silicon oxide, silicon nitride, silicon oxynitride, or any other suitable material having high etching selectivity relative to polysilicon. In some embodiments, this hard mask layer is patterned using photolithographic techniques, such as by forming a photoresist layer (not shown) atop the hard mask layer, patterning the photoresist layer, and/or using the patterned photoresist layer to pattern the hard mask in a subsequent etching step. The hard mask layer is then used as a pattern when etching underlying passivation layer 100, first polysilicon layer 70, gate dielectric layer 60, and/or oxide layer 50 to form the semiconductor device 10 shown in FIG. 1.

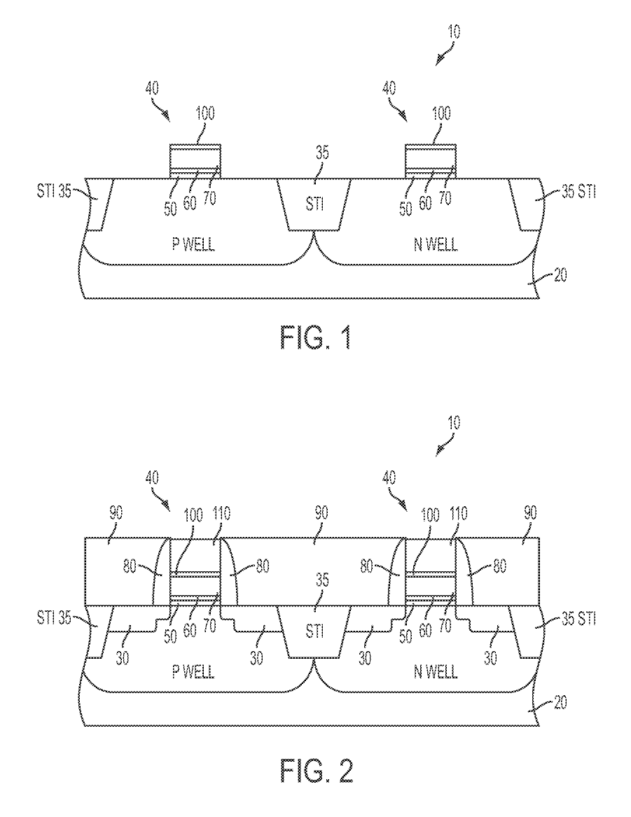

Referring now to FIG. 2, a second polysilicon layer 110 is formed over passivation layer 100. Second polysilicon layer 110 is formed similarly to the first polysilicon layer 70 using deposition procedures and materials. In some embodiments, the second polysilicon layer 110 has a thickness of from about 100 Angstroms to about 2,000, although other thicknesses are within the contemplated scope of the invention. Sidewall spacers 80 are formed on the sidewalls of the transistor 40 gate stack. Sidewall spacers 80 may be formed by conformally depositing one or more layers of oxide or nitride, followed by anisotropically etching the same. Sidewall seal liners (not shown) may be optionally formed on the sidewalls of the transistors 40 prior to the formation of the sidewall spacers 80. Source and drain regions 30 are formed in substrate 20 using known CMOS process flows. Source/drain regions 30 are formed on opposite sides of the gate stack of the transistors 40 and are implanted substantially aligned with the edges of the respective sidewall spacers 80. Obviously, one skilled in the art will recognize numerous variations from the described structure, including graded junctions, multiple sidewall spacer schemes, halo implants, pocket implants, and/or the like that are not necessary for understanding aspects of the invention, but that are nonetheless within the contemplated scope of embodiments of the invention.

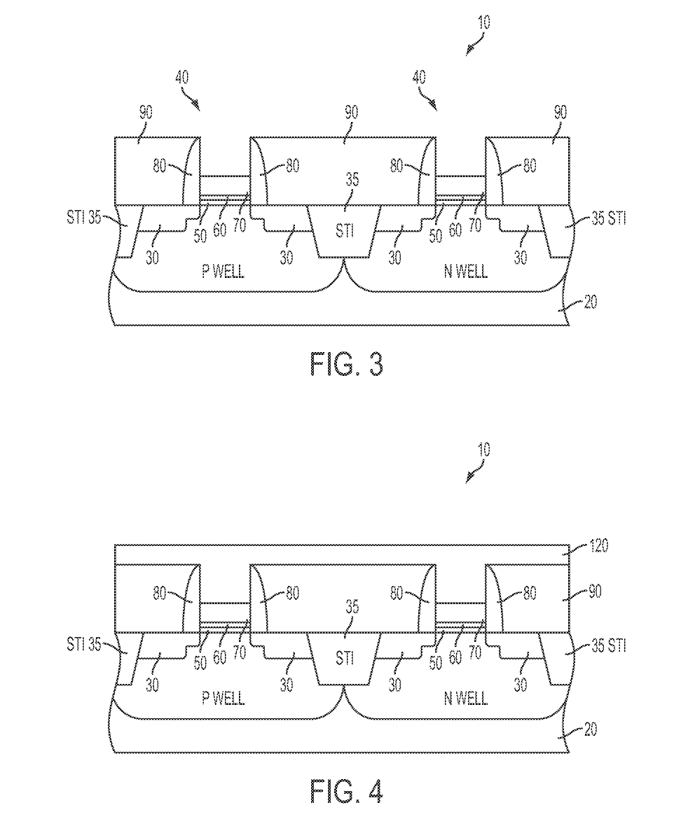

An inter-layer dielectric (ILD) layer 90 is deposited over the semiconductor device 10. ILD layer 90 provides a role of protecting the source and drain regions 30. ILD layer 90 may comprise spun-on-glass (SOG), high density plasma oxide, and/or the like. ILD layer 90 is then subjected to a chemical mechanical polish (CMP) process in which the top surface of the ILD layer 90 is planarized and lowered. CMP processing continues when the top surface of the second polysilicon layer 110 is reached resulting in the structure illustrated in FIG. 2. Next, using an appropriate etching process, such as dry etching or wet etching, second polysilicon layer 110 can be removed. Because of etching selectivity, the etching process stops at passivation layer 100. Subsequently, the passivation layer 100 can be removed, again using an etching process appropriate to the material of the passivation layer 100, such as wet etching. FIG. 3 illustrates the resulting structure after the second polysilicon layer 110 and the passivation layer 100 have been removed.

With reference now to FIG. 4, a metal layer 120 is blanket deposited over the semiconductor device 10 and above the exposed surface of the first polysilicon layer 70. In one embodiment, the metal layer 120 comprises nickel and may be deposited using applicable processes such as sputtering to a thickness of from about 100 Angstroms to about 1,600 Angstroms. In some other embodiments, metal layer 120 could comprise cobalt, copper, molybdenum, titanium, tantalum, tungsten, erbium, zirconium, platinum, ytterbium, or a combination thereof. Other metals are within the contemplated scope of the present invention as well.

A thermal process such as rapid thermal anneal (RTA) is then performed on semiconductor device 10 to cause metal layer 120 to interact with underlying first polysilicon layer 70 in order to form a fully silicided gate electrode 125. Numerous variations will be apparent to one skilled in the art with the benefit of the teachings contained herein and routine experimentation to obtain various fully silicided structures, including gate structures, of varying height.

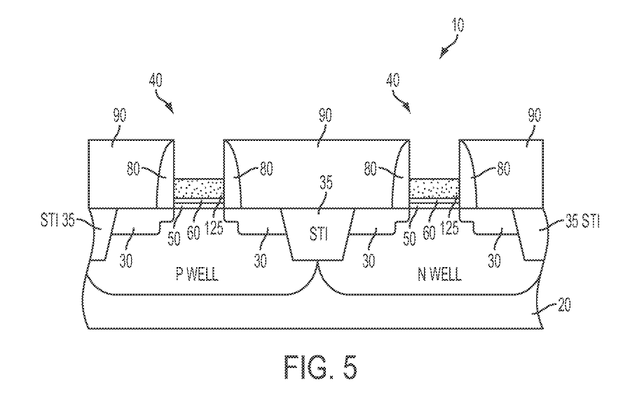

Following the silicidation step, the remaining metal layer 120 which does not interact with first polysilicon layer 70 is removed. FIG. 5 shows the resulting structure having fully silicided gate electrode 125. Processing can continue with the formation of one or more metal interconnect layers (not shown) separated by one or more inter-metal dielectric (IMD) layers (not shown), contacts (not shown), and connection with subsequently formed metal interconnects, as are known in the art for completing the semiconductor device 10.

The preceding disclosure was described with reference to exemplary embodiments of the present invention. It will, however, be evident that various modifications, structures, processes, and changes may be made thereto without departing from the broader spirit and scope of the embodiments of the present invention, as set forth in the claims. The specification and drawings are, accordingly, to be regarded as illustrative and not restrictive. It is understood that embodiments of the present invention are capable of using various other combinations and environments and can be changed or modified within the scope of the inventive concepts as expressed herein.

What is claimed is:

1. A method of fabricating a semiconductor device, comprising:
forming at least one gate structure on a substrate, the gate structure having a gate dielectric layer and a first polysilicon layer formed above the gate dielectric layer;
forming a passivation layer above the first polysilicon layer;
forming a second polysilicon layer above the passivation layer;
removing the second polysilicon layer by using the passivation layer as a stop layer;
removing the passivation layer;
forming a metal layer above the first polysilicon layer;
causing the first polysilicon layer to react with the metal layer to silicide the first polysilicon layer; and
removing un-reacted metal layer.

2. The method of claim 1, further comprising forming an oxide layer between the substrate and the gate dielectric layer.

3. The method of claim 1, wherein the first polysilicon layer has a thickness of from about 50 Angstroms to about 800 Angstroms.

4. The method of claim 1, wherein the passivation layer comprises oxide, silicon oxide, nitride, silicon nitride, or silicon oxynitride.

5. The method of claim 1, wherein the passivation layer has a thickness of from about 10 Angstroms to about 100 Angstroms.

6. The method of claim 1, wherein the second polysilicon layer has a thickness of from about 100 Angstroms to about 2,000 Angstroms.

7. The method of claim 1, wherein the metal layer comprises nickel, cobalt, copper, molybdenum, titanium, tantalum, tungsten, erbium, zirconium, platinum, ytterbium, or a combination thereof.

8. The method of claim 1, wherein the causing the first polysilicon layer to react comprises performing a rapid thermal anneal (RTA).

9. The method of claim 1, further comprising forming source and drain regions on opposite sides of the at least one gate structure.

10. The method of claim 1, further comprising forming spacers on the sidewalls of the gate structure.

11. The method of claim 1, wherein forming at least one gate structure comprises forming two gate structures.

12. The method of claim 11, wherein the two gate structures are separated by an isolation structure.

13. A method of forming a transistor, comprising:
forming a gate structure on a substrate, the gate structure having a gate dielectric layer and a first polysilicon layer formed above the gate dielectric layer;
forming a passivation layer above the first polysilicon layer;
forming a second polysilicon layer above the passivation layer;
removing the second polysilicon layer by using the passivation layer as a stop layer;
removing the passivation layer;
forming a metal layer above the first polysilicon layer;
causing the first polysilicon layer to react with the metal layer to silicide the first polysilicon layer;
removing un-reacted metal layer; and
forming source and drain regions on opposite sides of the gate structure.

14. The method of claim 13, wherein the first polysilicon layer has a thickness of from about 50 Angstroms to about 800 Angstroms.

15. The method of claim 13, wherein the passivation layer comprises oxide, silicon oxide, nitride, silicon nitride, or silicon oxynitride.

16. The method of claim 13, wherein the passivation layer has a thickness of from about 10 Angstroms to about 100 Angstroms.

17. The method of claim 13, wherein the second polysilicon layer has a thickness of from about 100 Angstroms to about 2,000 Angstroms.

18. The method of claim 13, wherein the metal layer comprises nickel, cobalt, copper, molybdenum, titanium, tantalum, tungsten, erbium, zirconium, platinum, ytterbium or a combination thereof.

19. The method of claim 13, wherein the causing the first polysilicon layer to react comprises performing a rapid thermal anneal (RTA).

20. The method of claim 13, further comprising forming source and drain regions on opposite sides of the at least one gate structure.
